(19) United States
(12) Patent Application Publication
(10) Pub. No.: US 2006/0043362 A1
(43) Pub. Date: Mar. 2, 2006

(54) Organic electroluminescent element and method of manufacturing the same

(75) Inventors: Shun-ichi Ishikawa, Kanagawa (JP); Takafumi Noguchi, Kanagawa (JP); Shotaro Ogawa, Shizuoka-ken (JP)

Correspondence Address: BIRCH STEWART KOLASCH & BIRCH, PO BOX 747, FALLS CHURCH, VA, 22040-0747, US

(73) Assignee: Fuji Photo Film Co., Ltd.

(21) Appl. No.: 11/210,795

(22) Filed: Aug. 25, 2005

(30) Foreign Application Priority Data
Aug. 27, 2004 (JP) 2004-248534

(51) Int. Cl. H01L 29/08

(52) U.S. Cl. 257/40

(57) ABSTRACT

An organic electroluminescent element comprising a transparent substrate and at least one organic layer containing a light-emitting layer between a pair of electrodes, wherein the transparent substrate is placed as the light output face of the element, a prism structure consisting of a prism pattern containing a medium having a refractive index of n1 and a prism pattern containing a medium having a refractive index of n2 are formed in that order from the side closer to the light-emitting layer between the transparent substrate and the electrode on the light output face of the organic layer, the ratio (n1/n2) is 1.5 or more, and the distance between the prism-side surface of the light-emitting layer and the bottom plane of the prisms is 100 μm or less organic electroluminescent element, and a method of manufacturing the organic electroluminescent element.

### CROSS-REFERENCE TO RELATED APPLICATION

This application claims priority under 35 USC 119 from Japanese Patent Application No. 2004-248534, the disclosure of which is incorporated by reference herein.

### BACKGROUND OF THE INVENTION

1. Field of the Invention

The present invention relates to an organic electroluminescent element (light-emitting element or EL element) that converts electric energy into light and emits light.

2. Description of the Related Art

Numerous programs in research and development on various display elements are underway today, and among them, organic electroluminescent (EL) elements, which emit high-brightness light at low voltage, have been attracting attention as promising display elements. However, organic electroluminescent elements remain significantly lower in luminous efficiency than inorganic LED elements and fluorescent lamps.

According to Thompson et al., external energy efficiency, an indicator of the luminous efficiency of an organic EL element, can be expressed as the product of internal energy efficiency and light output efficiency of an element (“Optics Letters”, 1997, Vol. 22, No. 6, p. 396). That is, for improvement of the luminous efficiency of an organic EL element, it is necessary to improve the internal energy efficiency as well as the light output efficiency of the element.

The light output efficiency is a ratio of the light emitted from the front transparent substrate face of the element into the air to the light generated in the element. The light generated in the light-emitting layer should pass through a number of interfaces between media different in refractive index before it is emitted into the air. According to Snell's Law of Refraction, light entering into each interface at an angle of not less than its critical angle is reflected totally by the interface back into the incident layer and consequently is eliminated there or released from the side face of the incident layer, resulting in decrease in the amount of the light emitted from the front face of the element. As a result, for example when the element is applied to a display, the display has lower front face brightness.

To overcome such problems, methods of suppressing the total reflection of light using a prism structure effective in converging light have been proposed.

For example, Japanese Patent No. 2931211 describes a method of preparing a substrate by placing a prism sheet manufactured by 3M on a glass having a thickness of 0.3 mm and adhering another glass having a thickness of 0.3 mm over the prism sheet, and then forming the organic EL element on the first glass to which the prism sheet is connected. The prism sheet, which is effective in converging light, alleviates the decrease in light output efficiency due to total reflection. However, the method disclosed in Japanese Patent No. 2931211 is aimed at preventing external light reflected by a mirror-surfaced electrode from disturbing the visibility of display when the device is not emitting light by using the prism sheet for light scattering, and as a result, use of the prism sheet disclosed in Patent No. 2931211 in a display device often causes a problem of bleeding of line images.

Alternatively, Japanese Patent Application Laid-Open (JP-A) No. 2003-86353 discloses a method of coating a thermosetting resin on a glass substrate to a thickness of 3 μm, hardening the resin by heating under an applied mold having prisms of 2 μm in base length and 2 μm in height, coating and hardening a polyimide resin thereon after removal of the mold and smoothing the surface of the resin film, and forming an organic EL element thereon. The organic EL element obtained by this method is problematic in terms of lower light-converging efficiency.

Accordingly, there exists no organic electroluminescent element that satisfies the requirements for use in a display application that demands high brightness as well as high contrast (for example, high visibility of smaller characters).

### SUMMARY OF THE INVENTION

In a first aspect of the present invention provides an organic electroluminescent element comprising:

a transparent substrate and at least one organic layer containing a light-emitting layer between a pair of electrodes, wherein

the transparent substrate is provided at a light output face of the element;

a prism structure, consisting of a prism pattern containing a medium having a refractive index of n1 and a prism pattern containing a medium having a refractive index of n2 formed in that order from a side closer to the light-emitting layer, is provided between the transparent substrate and an electrode on a light output face side;

the ratio n1/n2) is 1.5 or more; and

the distance between a prism-side surface of the light-emitting layer and a bottom plane of prisms in the prism structure is 100 μm or less.

In a second aspect of the invention provides a method of manufacturing an organic electroluminescent element having at least one organic layer containing a light-emitting layer between a pair of electrodes, the method comprising:

forming a prism pattern on a transparent first base material using a medium having a refractive index of 1.5 or more in the entire visible wavelength range;

forming a substrate having a prism structure by adhering the prism pattern to a transparent second base material so that the prism vertexes in the prism pattern come into contact with the transparent second base material; and

forming an anode, an organic layer, and a cathode on the transparent first base material-side surface of the substrate having a prism structure.

In a third aspect of the invention provides a method of manufacturing an organic electroluminescent element having at least one organic layer containing a light-emitting layer between a pair of electrodes, the method comprising:

forming a prism pattern on a transparent first base material using a medium having a refractive index of 1.5 or more in the entire visible wavelength range;

forming a substrate having a prism structure by adhering the prism pattern to a transparent second base material so that the prism vertexes in the prism pattern come into contact with the transparent second base material; and

adhering a cathode-side surface of a third base material, having an anode, an organic layer, and a photopermeable cathode formed thereon in that order, onto the transparent first base material-side surface of the substrate having the prism structure.

In a fourth aspect of the invention provides a method of manufacturing an organic electroluminescent element having at least one organic layer containing a light-emitting layer between a pair of electrodes, the method comprising:

forming a prism pattern on a first base material using a medium having a refractive index of 1.5 or more in the entire visible wavelength range;

forming a substrate having a prism structure by adhering the prism pattern to a transparent second base material so that the prism vertexes in the prism pattern come into contact with the transparent second base material, and then removing the first base material; and

forming an anode, an organic layer, and a cathode on the prism structure-side surface of the substrate having a prism structure.

In a fifth aspect of the invention provides a method of manufacturing an organic electroluminescent element having at least one organic layer containing a light-emitting layer between a pair of electrodes, the method comprising:

forming a prism pattern on a first base material using a medium having a refractive index of 1.5 or more in the entire visible wavelength range;

forming a substrate having a prism structure by adhering the prism pattern to a transparent second base material so that the prism vertexes in the prism pattern come into contact with the transparent second base material, and then removing the first base material; and

adhering a cathode-side surface of a third base material, having an anode, an organic layer, and a photopermeable cathode formed thereon in that order, onto the prism structure-side surface of the substrate having the prism structure.

### BRIEF DESERIPTION OF THE DRAWING

FIG. 1 is a schematic sectional view illustrating an example of the layer structure of the organic electroluminescent element according to the invention.

### DETAILED DESCRIPTION OF THE INVENTION

The present invention is achieved by the following means:

<1> An organic electroluminescent element comprising a transparent substrate and at least one organic layer containing a light-emitting layer between a pair of electrodes, wherein the transparent substrate is placed at the light output face of the element, a prism structure consisting of a prism pattern containing a medium having a refractive index of n1 and a prism pattern containing a medium having a refractive index of n2 are formed in that order from the side closer to the light-emitting layer between the transparent substrate and the electrode on the light output face side, the ratio n1/n2) is 1.5 or more, and the distance between the prism-side surface of the light-emitting layer and the bottom plane of the prisms is 100 μm or less [hereinafter, referred to as “organic electroluminescent element (1)”];

<2> The organic electroluminescent element described in <1>, wherein the distance between the prism-side surface of the light-emitting layer and the bottom plane of the prisms is 50 μm or less;

<3> The organic electroluminescent element described in <1>, wherein the refractive index of all layers present between the light-emitting layer and the prism structure is not less than the refractive index of the light-emitting layer, and the refractive index (n1) is not less than the refractive index of the light-emitting layer;

<4> An organic electroluminescent element comprising a transparent substrate and at least one organic layer containing a light-emitting layer between a pair of electrodes, wherein the transparent substrate is placed as the light output face of the element, a prism structure having a prism pattern containing a medium having a refractive index of 1.5 or more in the entire visible wavelength range and an aperture partitioned by the prism pattern and the transparent substrate formed in that order from the light-emitting layer side between the transparent substrate and the electrode on the light output face side, and the distance between the prism-side surface of the light-emitting layer and the bottom plane of the prisms is 100 μm or less [hereinafter, referred to as “organic electroluminescent element (2)”];

<5> The organic electroluminescent element described in <4>, wherein the distance between the prism-side surface of the light-emitting layer and the bottom plane of the prisms is 50 μm or less;

<6> The organic electroluminescent element described in <4>, wherein the refractive index of all layers present between the light-emitting layer and the prism structure is not less than the refractive index of the light-emitting layer, and the refractive index of the medium constituting the prism structure is not less than the refractive index of the light-emitting layer;

<7> A method of manufacturing an organic electroluminescent element having at least one organic layer containing a light-emitting layer between a pair of electrodes, comprising a step of forming a prism pattern by using a medium having a refractive index of 1.5 or more in the entire visible wavelength range on a transparent first base material, step of forming a substrate having a prism structure by adhering the prism pattern to a second transparent base material so that the prism vertexes in the prism pattern come in contact with the transparent second base material, and a step of forming an anode, an organic layer, and a cathode on the transparent first base material-side surface of the substrate having a prism structure [hereinafter, referred to as “method of manufacture (1)”];

<8> A method of manufacturing an organic electroluminescent element having at least one organic layer containing a light-emitting layer between a pair of electrodes, comprising a step of forming a prism pattern by using a medium having a refractive index of 1.5 or more in the entire visible wavelength range on a transparent first base material, a step of forming a substrate having a prism structure by adhering the prism pattern to a transparent second base material so that the prism vertexes in the prism pattern come in contact with the transparent second base material, and a step adhering the cathode-side surface of a substrate having an anode, an organic layer, and a photopermeable cathode formed on a third base material in that order onto the first base material-side surface of the substrate having a prism structure [hereinafter, referred to as “method of manufacture (2)”];

<9> A method of manufacturing an organic electroluminescent element having at least one organic layer containing a light-emitting layer between a pair of electrodes, comprising a step of forming a prism pattern by using a medium having a refractive index of 1.5 or more in the entire visible wavelength range on a first base material, a step of forming a substrate having a prism structure by adhering the prism pattern to a transparent second base material so that the prism vertexes in the prism pattern come in contact with the transparent second base material and then removing the first base material, and a step of forming an anode, an organic layer, and a cathode on the prism structure-side surface of the substrate having a prism structure [hereinafter, referred to as “method of manufacture (3)”]; and

<10> A method of manufacturing an organic electroluminescent element having at least one organic layer containing a light-emitting layer between a pair of electrodes, comprising a step of forming a prism pattern by using a medium having a refractive index of 1.5 or more in the entire visible wavelength range on a first base material, a step of forming a substrate having a prism structure by adhering the prism pattern to a transparent second base material so that the prism vertexes in the prism pattern come in contact with the transparent second base material and then removing the first base material, and a step of adhering the cathode-side surface of a substrate having an anode, an organic layer, and a photopermeable cathode formed on a third base material in that order onto the prism structure-side surface of the substrate having a prism structure [hereinafter, referred to as “method of manufacture (4)”].

The invention provides an organic electroluminescent element allowing display of high-brightness, high-contrast images and of smaller characters superior in visibility, and a method of manufacturing the organic electroluminescent element.

Hereinafter, the invention will be described in detail.

[Organic Electroluminescent Element]

The organic electroluminescent element according to the invention is an organic electroluminescent element comprising a transparent substrate and at least one organic layer containing a light-emitting layer between a pair of electrodes, wherein the transparent substrate is placed as the light output face of the element, a prism structure consisting of a prism pattern containing a medium having a refractive index of n1 and a prism pattern containing a medium having a refractive index of n2 are formed in that order from the side closer to the light-emitting layer between the transparent substrate and the electrode on the light output face of the organic layer, the ratio n1/n2) is 1.5 or more, and the distance between the prism-side surface of the light-emitting layer and the bottom plane of the prisms is 100 μm or less [organic electroluminescent element (1)].

Another embodiment of the organic electroluminescent element according to the invention is an organic electroluminescent element comprising a transparent substrate and at least one organic layer containing a light-emitting layer between a pair of electrodes wherein the transparent substrate is placed as the light output face of the element, a prism structure having a prism pattern containing a medium having a refractive index of 1.5 or more in the entire visible wavelength range and an aperture partitioned by the prism pattern and the transparent substrate formed in that order from the light-emitting layer side between the transparent substrate and the electrode on the light output face side, and the distance between the prism-side surface of the light-emitting layer and the bottom plane of the prisms is 100 μm or less [organic electroluminescent element (2)].

In the organic electroluminescent element, the light generated in the light-emitting layer is emitted outward through the transparent substrate. In such a case, when present between the light-emitting layer and the transparent substrate, the prism structure converges the light, suppressing total reflection of the light and thus improving the brightness of the element when seen from the front.

The invention, in which the ratio of the refractive indexes (n1) and (n2) of the media constituting the prism structure to 1.5 or more and the distance between the prism-side surface of the light-emitting layer and the bottom plane of the prisms to 100 μm or less, enables high-brightness high-contrast image display and assures superior visibility of smaller characters when displayed.

The organic electroluminescent element (2), the most favorable embodiment of the organic electroluminescent elements (1), contains an aperture as the prism pattern containing a medium having a refractive index of n2. In the embodiment, a medium having a refractive index of 1.5 or more in the entire visible wavelength range corresponds to the medium having a refractive index of n1 and a gas such as air contained in the aperture to the medium having a refractive index of n2.

The organic electroluminescent element according to the invention has a prism structure consisting of a prism pattern containing a medium having a refractive index of n1 and a prism pattern containing a medium having a refractive index of n2 between the transparent substrate and the electrode on the light output face formed in that order from the side closer to the light-emitting layer, and the ratio of refractive indexes of the two media n1/n2) constituting the prism structure should be 1.5 or more.

Generally, a prism means a transparent material having two or more optical planes, at least a pair of which are not even closely in parallel. Prisms are effective in converging light and thus have been used as optical parts. For example, so-called prism sheets, which have numerous V-shaped grooves aligned in parallel at a pitch of dozens to hundreds of microns formed over one entire surface of a plastic film, have been used for converging back light in liquid crystal display devices. In such a case, prisms having a wavy face or those having prisms with rounded edges are also used for the same purpose. The prism structures according to the invention also include those prism structures having a curved face or rounded prism edges.

The prism structure according to the invention consists of a prism pattern containing a medium having a refractive index of n1 and a prism pattern containing a medium having a refractive index of n2 formed in that order from the side closer to the light-emitting layer.

In the invention, the ratio of the refractive indexes (n1) and (n2) of the media constituting the prism structure n1/n2) should be 1.5 or more. The refractive index ratio n1/n2) is controlled, for example, by selection of the kinds of the media.

Generally, the refractive index varies according to the wavelength of the light used, but the requirement above should be satisfied at least over the visible wavelength region.

As described above, the organic electroluminescent element (2), a favorable embodiment of the invention, uses a medium having a refractive index of 1.5 or more in the entire visible wavelength range as the prism pattern containing a medium having a refractive index of n1, and an aperture as the prism pattern containing a medium having a refractive index of n2.

In this embodiment, the medium having a refractive index of 1.5 or more in the entire visible wavelength range and the aperture function as the prism structure in combination. The aperture may contain a gas such as nitrogen or argon that is inert to the organic EL element.

In a more specific configuration, the prism structure according to the invention has, for example, has a transparent medium (polymer, etc.) having V-shaped grooves formed at a certain pitch on the surface thereof (or on the opposite face when seen from the light-emitting layer side) as the prism pattern containing a medium having a refractive index of n1, and another transparent medium (polymer, air, etc.) different in refractive index filled in the V-shaped grooves as the prism pattern containing a medium having a refractive index of n2.

The grooves may be formed mono-, bi-, tri-, or poly-directionally; the grooves become pyramidal in shape when formed in two orthogonal directions and triangular when formed in three directions at a pitch of 60 degrees. In the invention, prism structures having grooves formed in one direction or in two orthogonal directions (pyramidal in shape) are preferable from the viewpoint of convergence efficiency and productivity.

The pitch between prisms exerts relatively smaller influence on brightness, but a smaller pitch seemingly leads to improvement in contrast. In practice, the pitch between prisms is preferably 0.1 to 50 μm, more preferably 0.5 to 30 μm, and particularly preferably 1 to 20 μm, from the point of the productivity of prism structure.

Alternatively, a smaller prism apex angle leads to greater increase in brightness but also to decrease in contrast. On the contrary, a larger apex angle leads to smaller decrease in contrast but also to smaller improvement in brightness. Accordingly, the apex angle is preferably 60 to 120 degrees and more preferably around 90 degrees.

The medium having a refractive index of n1 and medium having a refractive index of n2 for use in the prism structure is not particularly limited, if the refractive index thereof satisfies the requirement in the refractive index ratio of the invention, and a transparent resin is favorably used. Typical examples of the resins include acrylic resins, epoxy resins, polyimide resins, polycarbonate resins, and the like; and acrylic and epoxy resins are more preferable from the point of ease of productivity As described above, in the case of the organic electroluminescent element (2), the medium having a refractive index n2 is a gas such as air.

Hereinafter, the process for manufacturing the prism structure according to the invention will be described more specifically with reference to examples, but the invention is not limited by these examples.

A pattern of V-shaped grooves is first formed on the surface of a transparent medium having a refractive index of n1. The V-shaped grooves may be formed directly on the transparent medium surface by mechanical processing during pattern formation, but use of a mold, for example of metal having a pre-formed pattern, is more preferable for more efficient production. Namely, a patterned medium is prepared by pouring a liquid medium into a mold, hardening the liquid medium by cooling or in a reaction by action of light or heat, and removing the hardened medium from the mold. The liquid medium to be poured may be a medium that forms the prism structure ultimately or an intermediate transfer medium such as silicone elastomer. Thus, the pattern transfer may be preformed repeatedly as needed.

After the prism pattern is formed on the surface of the medium having a refractive index of n1, another liquid medium that will have a refractive index of n2 after hardening is coated and hardened thereon as needed.

Alternatively, in the case of the organic electroluminescent element (2), after the prism pattern is formed on the surface of the medium having a refractive index of n1, a prism structure is then formed by adhering the prism pattern containing a medium having a refractive index of n1 obtained above onto a transparent substrate and thus forming an aperture partitioned by the prism pattern and the transparent substrate.

The prism structure according to the invention should be placed between the electrode on the light output face of the organic layer and the transparent substrate placed on the light output face of the element. The prism structure may be in contact directly with the electrode surface; or an additional transparent layer of other base material may be present between the prism structure and the electrode surface

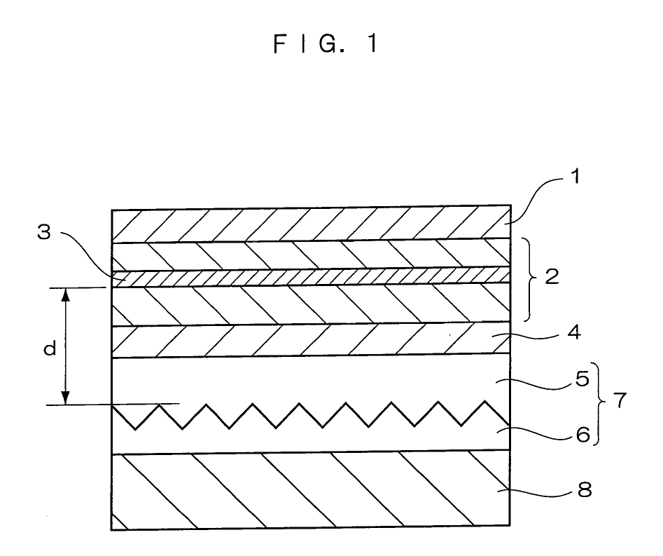

From the viewpoints above, in the organic electroluminescent elements according to the invention (1) and (2), the distance between the prism-side surface of the light-emitting layer and the bottom plane of the prisms should be 100 μm or less, but is preferably 50 μm or less for improving contrast. By controlling the distance between the prism-side surface of the light-emitting layer and the bottom plane of the prisms in this manner, it is possible to increase image visibility significantly, or more specifically, to allow more definite display of smaller characters on high-definition screen. The bottom plane of prisms means a plane of the prism pattern in the prism structure closest to the light-emitting layer, for example, the plane on which the bottom of the V-shaped grooves are located when they are formed. When the distance between the prism-side surface of the light-emitting layer and the bottom plane of the prisms is described more specifically with reference to a schematic sectional view (FIG. 1) illustrating an example of the organic electroluminescent element according to the invention, the distance d shown in FIG. 1 represents the distance between the prism-side surface of the light-emitting layer and the bottom plane of the prism. In FIG. 1, 1 and 4 represent a pair of electrodes; 2 represents an organic layer formed between the pair of electrodes 1 and 4; and 3 represents a light-emitting layer in the organic layer 2. 5 and 6 represents media respectively having refractive indexes of n1 and n2 and forming the prism patterns constituting the prism structure 7 in combination. 8 represents a transparent substrate.

The requirement in the distance above is based on the findings by the inventors that while displays prepared by using an organic electroluminescent element having a conventional prism structure often result in poor contrast, the factor exerting the greatest influence on the contrast is the distance between the prism-side surface of the light-emitting layer and the prism bottom plane, and that it is possible to increase the contrast by controlling the distance to 100 μm or less.

In addition, in the organic electroluminescent element according to the invention (1), the refractive index of all layers present between the light-emitting layer and the prism structure is preferably not less than the refractive index of the light-emitting layer, and the refractive index n1 is not less than the refractive index of the light-emitting layer for improvement in brightness. In the case of the organic electroluminescent element (2), the refractive index of all layers present between the light-emitting layer and the prism structure is preferably not less than the refractive index of the light-emitting layer, and the refractive index of the medium having a refractive index of 1.5 or more in the entire visible wavelength range is not less than the refractive index of the light-emitting layer.

If such conditions in refractive index are satisfied, almost all of the light emitted from the light-emitting layer enters into the prisms without total reflection on the way, improving brightness significantly.

Examples of the transparent substrates for use in the organic electroluminescent element according to the invention include quartz glass, nonalkali glass, soda lime glass, plastic films. The organic electroluminescent element may be a fluorescence- or phosphorescence-emitting element. Examples of other components such as electrode and organic layer in the electroluminescent element according to the invention include those described in JP-A Nos. 2004-221068, 2004-214178, 2004-146067, 2004-103577, 2003-323987, 2002-305083, 2001-172284, and 2000-186094, and others.

In addition, any mode of emission, for example a bottom emission mode of emitting light to the circuit board side of TFT or the like or a top emission mode of emitting light to the side opposite to the circuit board side of TFT or the like, may be used as the mode of the organic electroluminescent element according to the invention.

[Manufacture of Organic Electroluminescent Element]

The organic electroluminescent element according to the invention is an organic electroluminescent element containing the prism structure described above.

Hereinafter, the method of manufacturing the organic electroluminescent element according to the invention will be described, taking an organic electroluminescent element (2), the most favorable embodiment of the organic electroluminescent element according to the invention, as an example.

The following methods of manufacture (1) to (4) are favorably used for production of the organic electroluminescent element (2).

—Method of Manufacture (1)—

The method of manufacture (1) is a method of manufacturing an organic electroluminescent element having at least one organic layer containing a light-emitting layer between a pair of electrodes, comprising a step of forming a prism pattern of a transparent first base material by using a medium having a refractive index of 1.5 or more in the entire visible wavelength range on a transparent first base material (Step 1-1), a step of forming a substrate having a prism structure by adhering the prism pattern to a transparent second base material so that the prism vertexes in the prism pattern come in contact with the transparent second base material (Step 1-2), and a step of forming an anode, an organic layer, and a cathode on the first base material-side surface of the substrate having a prism structure (Step 1-3).

In Step 1-1, a prism pattern of a transparent first base material is formed, by using a medium having a refractive index of 1.5 or more in the entire visible wavelength range.

Examples of the transparent first base material used in this step include quartz glass, non-alkali glass, soda lime glass, plastic films, and the like.

The thickness of the transparent first base material may be determined arbitrarily; but in the invention, the distance between the prism-side surface of the light-emitting layer and the bottom plane of the prisms should be 100 μm or less, and the distance is normally adjusted according to the thickness of the first base material.

The specific method of forming the prism pattern in Step 1-1 is the same as that described in detail for the process for manufacturing the prism structure. The medium having a refractive index of 1.5 or more in the entire visible wavelength range used in the step is selected from the resins described for the process for manufacturing the prism structure.

In Step 1-2, a substrate having a prism structure is prepared by adhering the prism pattern to a transparent second base material so that the prism vertexes in the prism pattern obtained in Step 1-1 above come in contact with the transparent second base material.

A transparent base material similar to that for the transparent first base material is used for the transparent second base material used in Step 1-2. In addition, the prism pattern and the transparent second base material are adhered to each other, for example, by using a photocuring or thermosetting resin.

Then in Step 1-3, an anode, an organic layer, and a cathode are formed on the transparent first base material-side surface of the substrate having a prism structure obtained in Step 1-2.

With respect to the details of and the methods of producing the anode, organic layer, cathode, and others, those disclosed in the patent applications exemplified in description of the organic electroluminescent element according to the invention may be used similarly in this step.

—Method of Manufacture (2)—

The method of manufacture (2) is a method of manufacturing an organic electroluminescent element having at least one organic layer containing a light-emitting layer between a pair of electrodes, comprising a step of forming a prism pattern by using a medium having a refractive index of 1.5 or more in the entire visible wavelength range on a transparent first base material (Step 2-1), a step of forming a substrate having a prism structure by adhering the prism pattern to a transparent second base material so that the prism vertexes in the prism pattern come in contact with the transparent second base material (Step 2-2), a step of adhering the cathode-side surface of a substrate having an anode, an organic layer, and a photopermeable cathode formed of a third base material in that order onto the transparent first base material-side surface of the substrate having a prism structure (Step 2-3)

The method of manufacture (2) is a method used for production of so-called top-emission organic electroluminescent elements. Steps 2-1 and 2-2 are the same as Steps 1-1 and 1-2 in the method of manufacture (1).

In Step 2-3, in addition to the substrate having a prism structure a substrate having an anode, an organic layer, and a photopermeable cathode formed on a third base material in that order and the cathode-side surface of the substrate and the transparent first base material-side surface of the substrate having a prism structure are adhered to each other.

The third base material in Step 2-3 is the same as the first base material. The substrate having a prism structure and the substrate carrying the electrodes and organic layer are adhered to each other, for example, by using a photocuring or thermosetting resin.

With respect to the details of and the methods of producing the anode, organic layer, cathode, and others, those disclosed in the patent applications exemplified in description of the organic electroluminescent element according to the invention may be used similarly in this step.

In the methods of manufacture (1) and (2), the first base material is left in the organic electroluminescent element, and thus, the basic configuration of layers in the organic electroluminescent elements obtained by these methods is transparent substrate (second base material)/prism structure/transparent substrate (first base material)/electrode/organic layer/electrode.

The first base material may be eliminated as needed. The methods of manufacture (3) and (4) described below are embodiments of such methods. The basic configuration of the layers in each of the organic electroluminescent elements obtained by these methods is transparent substrate (second base material)/prism structure/electrode/organic layer/electrode.

—Method of Manufacture (3)—

The method of manufacture (3) is a method of manufacturing an organic electroluminescent element having at least one organic layer containing a light-emitting layer between a pair of electrodes, comprising a step of forming a prism pattern by using a medium having a refractive index of 1.5 or more in the entire visible wavelength range on a first base material (Step 3-1), a step of forming a substrate having a prism structure by adhering the prism pattern and a second transparent base material and then removing the first base material so that the prism vertexes in the prism pattern come in contact with the transparent second base material (Step 3-2), and a step of forming an anode, an organic layer, and a cathode on the prism structure-side surface of the substrate having a prism structure (Step 3-3).

The prism pattern in Step 3-1 is formed in a similar manner to Step 1-1 in the method of manufacture (1), but the first base material used here is a material that can be removed in Step 3-2. There is no requirement concerning transparency for the first base material used in this step, such as those for the first base material used in the methods of manufacture (1) and (2), because it is removed in the later Step.

Specific examples of the first base materials used in this Step include base materials that can be removed by solution treatment including water-soluble base materials such as PVA film and gelatin film, oil-soluble base materials such as polymethyl methacrylate film.

In Step 3-2, the prism pattern and the second transparent base material are adhered to each other in a similar manner to Step 1-2 in the method of manufacture (1), and then the first base material is removed.

The first base material may be removed after prism pattern formation, for example, by dissolving it with water when it is a water-soluble base material such as PVA film.

In Step 3-3, an anode, an organic layer, and a cathode are formed on the prism structure-side surface of the substrate having a prism structure obtained in Step 3-2. With respect to the details of and the methods of producing the anode, organic layer, cathode, and others, those disclosed in the patent applications exemplified in description of the organic electroluminescent element according to the invention may be used similarly in this step.

—Method of Manufacture (4)—

The method of manufacture (4) is a method of manufacturing an organic electroluminescent element having at least one organic layer containing a light-emitting layer between a pair of electrodes, comprising a step of forming a prism pattern by using a medium having a refractive index of 1.5 or more in the entire visible wavelength range on a first base material (Step 4-1), a step of forming a substrate having a prism structure by adhering the prism pattern above and a transparent second base material so that the prism vertexes in the prism pattern come in contact with the transparent second base material and then removing the first base material(Step 4-2), and a step of adhering the cathode-side surface of a substrate having an anode, an organic layer, and a photopermeable cathode formed on a third base material in that order onto the prism structure-side surface of the substrate having a prism structure (Step 4-3).

The method of manufacture (4) is a method for producing so-called top-emission organic electroluminescent elements.

Steps 4-1 and 4-2 are the same as Step 3-1 and 3-2 in the method of manufacture (3).

In Step 4-3, a substrate having an anode, an organic layer, and a photopermeable cathode formed on a third base material in that order in addition to the substrate having a prism structure, and the cathode-side surface of the substrate and the prism structure-side surface of the substrate having a prism structure are adhered to each other.

The method of adhering the third base material and the substrate having a prism structure to the substrate having an electrode and an organic layer and details about and the method of forming the anode, organic layer, cathode, and others in Step 4-3 are the same as those described in Step 2-3 of the method of manufacture (2).

The organic electroluminescent elements obtained by the methods of manufacture (3) and (4) have very thin layers formed between the prism-side surface of the light-emitting layer and the bottom plane of the prisms structure, and thus the distance between the prism-side surface of the light-emitting layer and the bottom plane of the prisms becomes 100 μm or less without particular adjustment.

### EXAMPLES

Hereinafter, the invention will be described with reference to Examples, but it should be understood that the invention is not restricted by these examples.

### Example 1

<Preparation of Organic EL Element>

(Preparation of Silicone Prism Pattern)

A Ni mold for a prism pattern having prism templates of an apex angle of 90 degrees and a pitch of 10 μm was prepared by cutting the surface of a Ni plate with a diamond bite. A silicone elastomer was applied and hardened thereon, and the silicone elastomer was removed from the mold, to give a silicone prism pattern.

(Preparation of Prism Structure)

A UV-curing resin (trade name: OG114, manufactured by Epoxy Technology Inc.; and refractive index after hardening: 1.5 or more in the entire visible wavelength range) was coated in an amount of 12 ml/m² on a glass base material having a thickness of 70 μm (first base material). Then, the silicone prism pattern above was fixed thereon under pressure, and the UV-resin layer was irradiated and thus hardened with a UV ray (365 nm) from the glass substrate side for 1 minute. Subsequent removal of the silicone prism pattern gave a base material carrying an epoxy resin prism pattern on the glass base material having a thickness of 70 μm.

The base material carrying the prism pattern thus obtained and the glass substrate having a thickness of 0.7 mm (second base material) were adhered to each other so that the prism vertexes in the prism pattern become in contact with the second base material, to give a substrate having a prism structure.

An anode (thickness: 0.15 μm) of indium tin oxide [ITO, indium/tin: 95/5 (molar ratio)] was formed by DC spattering on the first base material-side surface of the substrate having a prism structure thus obtained (i.e., the surface of first base material opposite to the prism pattern surface). The surface resistance of the anode was 10Ω/□.

An organic layer (organic hole-transporting layer and organic light-emitting layer) was formed over the anode.

First, an organic hole-transporting layer of N,N-dinaphthyl-N,N′-diphenylbenzidine having a thickness of 0.04 μm was formed by vacuum deposition. An organic light-emitting layer of tris(8-hydroxyquinolino)aluminum of 0.06 μm in thickness was then formed thereon by vacuum deposition.

Subsequently, magnesium and silver (molar ratio: 10:1) are deposited over the organic layer through a patterned mask to a thickness of 0.25 μm in a vapor deposition device and then silver to 0.3 μm in thickness, forming a cathode.

An organic EL element A of Example 1 was prepared by connecting aluminum lead wires to the anode and the cathode respectively.

In the organic EL element A, the ratio n1/n2) was 1.5, and the distance between the prism-side surface of the light-emitting layer and the prism bottom plane was approximately 80 μm.

### Example 2

An organic EL element B of Example 2 was prepared in a similar manner to Example 1 except that the glass base material having a thickness of 70 μm used as the first base material in Example 1 was replaced with a glass base material having a thickness of 30 μm.

In the organic EL element B, the ratio n1/n2) was 1.5, and the distance between the prism-side surface of the light-emitting layer and the prism bottom plane was approximately 40 μm.

### Example 3

A liquid dispersion containing 70% zirconium oxide particles having an average particle diameter of approximately 20 nm and 30% dipentaerythritol hexaacrylate was coated on a PVA film having a thickness of 50 μm (first base material) in an amount of 22 ml/m². The silicone prism pattern used in Example 1 was fixed thereon under pressure, and the coated layer was irradiated and thus hardened with a UV ray (365 nm) from the PVA side for 1 minute. Subsequent removal of the silicone pattern gave a base material carrying the prism pattern on the PVA film having a thickness of 50 μm.

The base material carrying the prism pattern thus obtained and a glass substrate of 0.7 mm in thickness (second base material) were adhered to each other so that the prism vertexes in the prism pattern come in contact with the second base material, and the PVA layer was removed by dissolving it with water, to give a substrate having a prism structure.

An anode, an organic light-emitting layer, and a cathode were formed in a similar manner to Example 1 on the prism structure-side surface of the substrate having a prism structure thus obtained (smooth surface), and aluminum lead wires are additionally connected to the anode and the cathode, to give a organic EL element C of Example 3.

In the organic EL element C, n1 was 1.7, which was almost the same as the refractive index of tris(8-hydroxyquinolino)aluminum, i.e., the organic light-emitting layer. In addition, because the refractive index of the anode was approximately 2.0, the refractive index of all layers present between the light-emitting layer and the prism structure was not less than the refractive index of the light-emitting layer. The ratio n1/n2) was 1.7, and the distance between the prism-side surface of the light-emitting layer and the prism bottom plane was approximately 20 μm.

### Comparative Example 1

An organic EL element D of Comparative Example 1 was prepared in a similar manner to Example 1, except that the glass base material having a thickness of 70 μm used as the first base material in Example 1 was replaced with a glass base material having a thickness of 0.1 mm.

In the organic EL element D, the ratio n1/n2) was 1.5, and the distance between the prism-side surface of the light-emitting layer and the prism bottom plane was approximately 110 μm.

### Comparative Example 2

An organic EL element E of Comparative Example 2 was prepared in a similar manner to Example 1, except that the glass base material having a thickness of 70 μm used as the first base material in Example 1 was replaced with a glass base material having a thickness of 0.2 mm.

In the organic EL element E, the ratio n1/n2) was 1.5, and the distance between the prism-side surface of the light-emitting layer and the prism bottom plane was approximately 210 μm.

### Comparative Example 3

An organic EL element F of Comparative Example 3 was prepared in a similar manner to Example 1, except that the glass base material having a thickness of 70 μm used as the first base material in Example 1 was replaced with a glass base material having a thickness of 0.3 mm.

In the organic EL element F, the ratio n1/n2) was 1.5, and the distance between the prism-side surface of the light-emitting layer and the prism bottom plane was approximately 310 μm.

### Comparative Example 4

A prism pattern having a refractive index (n1) of 1.7 was formed on a PVA film (first base material) in a similar manner to Example 3, and then, an acrylate-based monomer having a refractive index after hardening (n2) of approximately 1.5 (trade name: TB 3066, manufactured by Three Bond Co., Ltd.) was applied thereon in an amount of 8 ml/m² and hardened by UV irradiation, to give a base material carrying the prism pattern on the PVA film.

The base material carrying the prism pattern thus obtained was adhered onto a glass substrate having a thickness of 0.7 mm (second base material) so that the surface on the side of the resin having a refractive index of n2 came in contact with the second base material, and the PVA film was removed by dissolving it with water, to give a substrate having a prism structure.

An anode, an organic light-emitting layer, and a cathode were formed on the side of the resin having a refractive index of n1 (smooth surface) of the substrate having a prism structure obtained in a similar manner to Example 3, to give an organic EL element G of Comparative Example 4.

In the organic EL element G, the ratio n1/n2) was approximately 1.1, and the distance between the prism-side surface of the light-emitting layer and the prism bottom plane was approximately 30 μm.

### Comparative Example 5

An organic EL element H of Comparative Example 5 was prepared in a similar manner to Example 1, except that a fluorine-containing acrylate-based UV-curing resin (refractive index after hardening: 1.4) was used as the UV-curing resin in Example 1.

In the organic EL element H, the ratio n1/n2) was 1.4, and the distance between the prism-side surface of the light-emitting layer and the prism bottom plane was approximately 80 μm.

### Comparative Example 6

An organic EL element I of Comparative Example 6 was prepared in a similar manner to Example 1, except that the prism structure of Example 1 was not formed and an anode, an organic light-emitting layer, and a cathode were formed directly on a glass substrate of 0.7 mm in thickness.

<Evaluation>

1. Evaluation of Brightness

Each of the elements obtained in Examples and Comparative Examples was allowed to emit light under application of a direct current voltage of 12 V The brightness of each element was determined, relatively to the brightness of organic EL element I of 1 and the relative value was used as an indicator of brightness. Results are summarized in Table 1 below.

2. Evaluation of Visibility

The visibility was evaluated, by forming a display device by using each of the organic EL elements obtained in Examples and Comparative Examples, displaying a pattern of lines having a width of 200 μm aligned in parallel at a pitch of 200 μm, and observing the visibility of the line image. The results are evaluated by 5-point method. A score of 4 points or more in this evaluation indicates a level allowing definite display of 7-point characters (for example, alphabet H) on the screen. Results are summarized in the following Table 1.

TABLE 1

| | | | | | Distance between | Improvement | Visibility |
|---|---|---|---|---|---|---|---|
| | Organic EL | | | | light-emitting | in | of line |
| | element | n1 | n2 | n1/n2 | layer and prism | brightness | image |
| Example 1 | Organic EL | 1.5 | 1 | 1.5 | 80 μm | 1.8 | 4 |
| | element-A | | | | | | |
| Example 2 | Organic EL | 1.5 | 1 | 1.5 | 40 μm | 1.8 | 5 |
| | element-B | | | | | | |
| Example 3 | Organic EL | 1.7 | 1 | 1.7 | 20 μm | 2.4 | 5 |
| | element-C | | | | | | |
| Comparative | Organic EL | 1.5 | 1 | 1.5 | 110 μm | 1.8 | 3 |
| Example 1 | element-D | | | | | | |
| Comparative | Organic EL | 1.5 | 1 | 1.5 | 210 μm | 1.8 | 2 |
| Example 2 | element-E | | | | | | |
| Comparative | Organic EL | 1.5 | 1 | 1.5 | 310 μm | 1.8 | 1 |
| Example 3 | element-F | | | | | | |
| Comparative | Organic EL | 1.7 | 1.5 | 1.1 | 30 μm | 1.1 | 5 |
| Example 4 | element-G | | | | | | |
| Comparative | Organic EL | 1.4 | 1 | 1.4 | 80 μm | 1.4 | 4 |
| Example 5 | element-H | | | | | | |
| Comparative | Organic EL | — | — | — | — | 1 | 5 |
| Example 6 | element-I | | | | | | |

In Table 1 above, the “distance between light-emitting layer and prism” means a “distance between the prism-side surface of the light-emitting layer and the bottom of the V-shaped grooves in prism structure” (see d in FIG. 1).

As apparent from Table 1 above, the organic EL elements obtained in Examples 1 to 3 were better both in the improvement in brightness and the visibility of line image than the organic EL elements obtained in Comparative Examples. The organic EL elements according to the invention were organic EL elements allowing display of high-brightness, high-contrast image as well as high-visibility display of smaller characters even when used for the purpose.

The organic electroluminescent elements obtained according to the invention may be favorably used in various fields including display element, display, back light, electrophotography, luminescent light source, recording light source, exposure light source, data-reading light source, sign and mark, signboard, interior goods, optical communication.

What is claimed is:

1. An organic electroluminescent element comprising:
a transparent substrate and at least one organic layer containing a light-emitting layer between a pair of electrodes, wherein
the transparent substrate is provided at a light output face of the element;
a prism structure, consisting of a prism pattern containing a medium having a refractive index of n1 and a prism pattern containing a medium having a refractive index of n2 formed in that order from a side closer to the light-emitting layer, is provided between the transparent substrate and an electrode on a light output face side;
the ratio n1/n2) is 1.5 or more; and
the distance between a prism-side surface of the light-emitting layer and a bottom plane of prisms in the prism structure is 100 μm or less.

2. The organic electroluminescent element according to claim 1, wherein the distance between the prism-side surface of the light-emitting layer and the bottom plane of the prisms is 50 μm or less.

3. The organic electroluminescent element according to claim 1, wherein the refractive index of a layer present between the light-emitting layer and the prism structure is not less than the refractive index of the light-emitting layer and the refractive index (n1) is not less than the refractive index of the light-emitting layer.

4. The organic electroluminescent element according to claim 1, wherein an additional transparent substrate is formed between the prism structure and the electrode on the light output face side.

5. The organic electroluminescent element according to claim 1, wherein the prism pattern has grooves aligned in one direction or two orthogonal directions.

6. The organic electroluminescent element according to claim 1, wherein prisms at a pitch of 0.1 to 50 μm are formed in the prism pattern.

7. The organic electroluminescent element according to claim 1, wherein prisms having an apex angle of 60 to 120 degrees are formed in the prism pattern.

8. The organic electroluminescent element according to claim 1, wherein each of the medium having a refractive index of n1 and the medium having a refractive index of n2 is a transparent resin selected from the group consisting of acrylic resins, epoxy resins, polyimide resins, and polycarbonate resins.

9. The organic electroluminescent element according to claim 1, wherein the medium having a refractive index of n1 has a refractive index of 1.5 or more in the entire visible wavelength range and the prism pattern containing a medium having a refractive index of n2 consists of an aperture partitioned by the prism pattern and the transparent substrate.

10. The organic electroluminescent element according to claim 9, wherein the aperture partitioned by the prism pattern and the transparent substrate is filled with air.

11. The organic electroluminescent element according to claim 9, wherein the distance between the prism-side surface of the light-emitting layer and the bottom plane of the prisms is 50 μm or less.

12. The organic electroluminescent element according to claim 9, wherein the refractive index of a layer present between the light-emitting layer and the prism structure is not less than the refractive index of the light-emitting layer and the refractive index of the medium for the prism structure having a refractive index of 1.5 or more in the entire visible wavelength range is not less than the refractive index of the light-emitting layer.

13. The organic electroluminescent element according to claim 9, wherein an additional transparent substrate is formed between the prism structure and the electrode on the light output face side.

14. A method of manufacturing an organic electroluminescent element having at least one organic layer containing a light-emitting layer between a pair of electrodes, the method comprising:
forming a prism pattern on a transparent first base material using a medium having a refractive index of 1.5 or more in the entire visible wavelength range;
forming a substrate having a prism structure by adhering the prism pattern to a transparent second base material so that the prism vertexes in the prism pattern come into contact with the transparent second base material; and
forming an anode, an organic layer, and a cathode on the transparent first base material-side surface of the substrate having a prism structure.

15. A method of manufacturing an organic electroluminescent element having at least one organic layer containing a light-emitting layer between a pair of electrodes, the method comprising:
forming a prism pattern on a transparent first base material using a medium having a refractive index of 1.5 or more in the entire visible wavelength range;
forming a substrate having a prism structure by adhering the prism pattern to a transparent second base material so that the prism vertexes in the prism pattern come into contact with the transparent second base material; and
adhering a cathode-side surface of a third base material, having an anode, an organic layer, and a photopermeable cathode formed thereon in that order, onto the transparent first base material-side surface of the substrate having the prism structure.

16. A method of manufacturing an organic electroluminescent element having at least one organic layer containing a light-emitting layer between a pair of electrodes, the method comprising:
forming a prism pattern on a first base material using a medium having a refractive index of 1.5 or more in the entire visible wavelength range;
forming a substrate having a prism structure by adhering the prism pattern to a transparent second base material so that the prism vertexes in the prism pattern come into contact with the transparent second base material, and then removing the first base material; and
forming an anode, an organic layer, and a cathode on the prism structure-side surface of the substrate having a prism structure.

17. A method of manufacturing an organic electroluminescent element having at least one organic layer containing a light-emitting layer between a pair of electrodes, the method comprising:
forming a prism pattern on a first base material using a medium having a refractive index of 1.5 or more in the entire visible wavelength range;
forming a substrate having a prism structure by adhering the prism pattern to a transparent second base material so that the prism vertexes in the prism pattern come into contact with the transparent second base material, and then removing the first base material; and
adhering a cathode-side surface of a third base material, having an anode, an organic layer, and a photopermeable cathode formed thereon in that order, onto the prism structure-side surface of the substrate having the prism structure.
